(19) United States
(12) Patent Application Publication
(10) Pub. No.: US 2026/0359686 A1
(43) Pub. Date: Nov. 12, 2026

(54) AUTOREGRESSIVE BASED DATA COMPRESSION

(71) Applicant: City University of Hong Kong, Kowloon, Hong Kong (CN)

(72) Inventors: Yu Mao, Kowloon, Hong Kong (CN); Chn Xue, Kowloon, Hong Kong (CN); Tei-Wei Kuo, Taipei, Taiwan (CN)

(21) Appl. No.: 19/486,981

(22) PCT Filed: Jun. 14, 2025
(86) PCT No.: PCT/CN2024/099195

§ 371 Date: Nov. 24, 2025

Related U.S. Application Data
(60) Provisional application No. 63/512,089, filed on Jul. 6, 2023.

(51) Int. Cl. G06N 7/01

(52) U.S. Cl. CPC G06N 7/01

(57) ABSTRACT

A method for autoregressive based compression of a dataset with a plurality of data units includes using a neural network based probability estimator, determining a probability associated with a target data unit based on one or more previous data units associated with the target data unit, and using a coder, coding the target data unit based on the target data unit and the determined probability associated with the target data unit.

### TECHNICAL FIELD

The present invention generally relates to autoregressive (AR) based data compression.

### BACKGROUND

With the proliferation of Internet of Things (IoT) infrastructures and the 5G techniques, data volume that needs to be transmitted and stored has expanded considerably [1], [2]. General-purpose lossless data compression techniques are potential solutions to reduce data sizes. However, standard compressors like Gzip [3] and Zstandard [4] have limited performance on multi-modal data streams due to their dictionary-based nature. The rapid development of deep learning techniques raised a number of neural-network-based compressors. Those compressors model the compression task as an AutoRegressive (AR) sequential modeling problem. AR-based compressors take a set of adjacent compressed symbols as input to estimate the probability of the following symbol (referred to as “history symbols” and “target symbol” hereinafter), and can achieve substantially improvement on compression ratios. Nonetheless, the running speed of these deep learning-based compressors is far from satisfactory.

### SUMMARY OF THE INVENTION

Neural AutoRegressive (AR) framework has recently been applied in general-purpose lossless compression to improve compression performance. Inventors of the present invention have found, however, that directly applying the original AR framework can cause duplicated processing problem and/or in-batch distribution variation problem, which lead to deteriorated compression performance. Inventors of the present invention have devised, through their research, experiments, and trials, that one way to address the duplicated processing problem is to disentangle the processing of the history symbol set at the input side. To this end, inventors of the present invention propose, in some embodiments, two new types of neural blocks. The first type of neural block is individual-block, which performs separate feature extraction on each history symbol. The second type of neural block is mix-block, which models the correlation between extracted features and estimates the probability. Inventors of the present invention propose, in some embodiments, a progressive AR-based compression framework (PAC), which only requires one history symbol from the host at a time rather than the whole history symbol set. In some embodiments, a trainable matrix multiplication is introduced to model the ordered importance, replacing the existing hardware-unfriendly Gumble-Softmax sampling. Inventors of the present invention have found that the in-batch distribution variation problem is caused by structured batch construction of AR-based compression. Thus, inventors of the present invention propose, in some embodiments, a batch-location-aware individual block to capture the heterogeneous in-batch distributions more precisely, thereby improving the performance without efficiency losses. Example experimental results show that the framework in some embodiments can achieve an average of 130% speed improvement with an average of 3% compression ratio gain across data domains compared to the existing state-of-the-art methods.

In a first aspect, there is provided an autoregressive (AR) based data compression framework that includes one or more of the following features: (a) an individual-mix block architecture, (b) a feature cache, (c) a learned ordered importance mechanism, (d) a batch-location-aware design.

The individual-mix block architecture may include one or more individual-mix blocks each comprising an individual block for feature extraction and a mix block for correlation modeling and probability estimation. In some examples, the individual-mix block architecture may have multiple individual-mix blocks with different output sizes and/or the multiple individual-mix blocks with different output sizes may be stacked, for enhancing compression performance.

The feature cache may be arranged for storing extracted features (e.g., features extracted by the individual block). This may facilitate independent processing of history symbols and/or reduce duplicated processing. In some examples, the feature cache may enable efficient management of the storage of extracted features hence optimizing (e.g., reducing) CPU-GPU data transmission/communication/processing time and resources.

The learned ordered importance mechanism may include (e.g., may consist only of) matrix arithmetic (e.g., addition and multiplication) operations. This may enable efficient estimation of symbol importance. In some examples, the learned ordered importance mechanism may be arranged to utilize a trainable 1D vector for assigning importance scores to the extracted features. This may simplify or facilitate hardware compatibility.

The batch-location-aware design may assign distinct parameters to different positions in the batch to capture in-batch distribution variation. In some examples, the batch-location-aware modification may optimize the individual layer (e.g., individual blocks) to address in-batch distribution variation. This may improve compression performance).

In a second aspect, there is provided a system comprising one or more processors and memory storing one or more programs configured to be executed by the one or more processors. The one or more programs include instructions for implementing or facilitating implementation of the autoregressive (AR) based data compression framework of the first aspect.

In a third aspect, there is provided a method (computer-implemented method) for autoregressive based compression of a dataset. The dataset includes multiple data units. The method includes: using a neural network based probability estimator, determining a probability associated with a target data unit based on one or more previous data units associated with the target data unit. The method further includes: using a coder, coding the target data unit based on the target data unit and the determined probability associated with the target data unit.

In some embodiments of the third aspect, determining the probability associated with the target data unit comprises: using the neural network based probability estimator: performing feature extraction operation for each respective one of the one or more previous data units associated with the target data unit to extract one or more features of the one or more previous data units associated with the target data unit, and performing feature mixture operation based on the one or more extracted features of the one or more previous data units associated with the target data unit to perform correlation modelling and to determine the probability associated with a target data unit.

In some embodiments of the third aspect, the one or more extracted features of the one or more previous data units comprises a plurality of extracted features of a plurality of previous data units. In some embodiments of the third aspect, the method further comprises: prior to performing the feature mixture operation, assigning respective importance score to each of the extracted features to facilitate performing of the feature mixture operation. In some embodiments of the third aspect, the assigning comprises applying a trainable or trained ordered mask to the extracted features. In some embodiments of the third aspect, the trainable or trained ordered mask comprises a 1D vector.

In some embodiments of the third aspect, the feature extraction operation is performed by one or more individual blocks of the neural network based probability estimator. Each of the one or more individual blocks is arranged for performing feature extraction operation on a respective one of the one or more previous data units.

In some embodiments of the third aspect, each of the one or more individual blocks respectively comprises a fully connected layer (e.g., one fully connected layer). In some embodiments of the third aspect, the one or more individual blocks are multilayer perceptron (MLP) based.

In some embodiments of the third aspect, the feature mixture operation is performed by a mix block of the neural network based probability estimator.

In some embodiments of the third aspect, the mix block comprises a plurality of fully connected layers (e.g., two fully connected layers). In some embodiments of the third aspect, the mix block is multilayer perceptron (MLP) based.

In some embodiments of the third aspect, the method further comprises: prior to performing the feature extraction operation, transmitting the one or more previous data units associated with the target data unit from a first processor (e.g., CPU) to a second processor (e.g., GPU). The feature extraction operation and the feature mixture operation may be performed at the second processor (e.g., GPU).

In some embodiments of the third aspect, the method further comprises: caching the extracted features of the one or more previous data units in a cache of the second processor (e.g., GPU).

In some embodiments of the third aspect, the method further comprises: prior to performing the feature mixture operation, retrieving the one or more extracted features of the one or more previous data units from the cache of the second processor (e.g., GPU).

In some embodiments of the third aspect, the plurality of data units of the dataset form a plurality of data subsets each including multiple data units. In some embodiments of the third aspect, the dataset defines a plurality of batches each including one respective data unit from each respective one of the data subsets. In some embodiments of the third aspect, the data units in the same batch are processed the same processing cycle (e.g., the same timestep), and the data units in different batches are processed in different processing cycles (e.g., different timesteps).

In some embodiments of the third aspect, in each processing cycle, each of the data units in the corresponding batch corresponds to a respective target data unit (which is processed using the method).

In some embodiments of the third aspect, each batch respectively includes data units taken from the same location in the plurality of data subsets.

In some embodiments of the third aspect, the one or more individual blocks of the neural network based probability estimator are one or more batch-location-aware individual blocks.

In some embodiments of the third aspect, the coder comprises an entropy coder (e.g., arithmetic coder).

In some embodiments of the third aspect, the dataset comprises image data, video data, text data, or audio data.

In some embodiments of the third aspect, each of the plurality of data units respectively correspond to bit(s), byte(s), or token(s).

In a fourth aspect, there is provided a system for autoregressive based compression of a dataset with a plurality of data units. The system comprises one or more processors and memory storing one or more programs configured to be executed by the one or more processors. The one or more programs include instructions for performing or facilitating performing of the method of the third aspect. In some embodiments of the fourth aspect, the one or more processors comprises a first processor (e.g., CPU) and a second processor (e.g., GPU).

In a fifth aspect, there is provided non-transitory computer-readable storage medium storing one or more programs configured to be executed by one or more processors. The one or more programs include instructions for performing or facilitating performing of the method of the third aspect.

Other features and aspects of the disclosure will become apparent by consideration of the detailed description and accompanying drawings. Any feature(s) described herein in relation to one aspect or embodiment may be combined with any other feature(s) described herein in relation to any other aspect or embodiment as appropriate and applicable.

### BRIEF DESCRIPTION OF DRAWINGS

Example embodiments of the invention will now be described, by way of example, with reference to the accompanying drawings. A brief description of the drawings are as follows:

FIG. 1: Illustration of duplicated processing problem and how some embodiments of the invention address it. The illustration on the left hand side shows the probability estimator under the traditional auto-regressive compression framework, which requires repeated transmission and processing of a symbol. The illustration on the right hand side shows the proposed framework in some embodiments of the invention, in which a symbol is transmitted and extracted only once.

FIG. 2A: Illustration of structured batch construction and in-batch distribution variation problem. For the distribution figures (i), (ii), (iii) and (iv), the x-axis is the byte value and the y-axis is the number of byte value.

FIG. 2B: Enlarged distribution figures (i), (ii), (iii) and (iv) of FIG. 2A. The x-axis is the byte value and the y-axis is the number of byte value.

FIG. 3: Illustration of the progressive AR-based compression framework in some embodiments of the invention.

FIGS. 4A and 4B: Examples of sampled ordered masks and trained ordered masks in some embodiments of the invention. FIG. 4A shows the Gumble-Softmax sampled ordered mask. FIG. 4B shows the proposed learned ordered mask in some embodiments of the invention.

FIGS. 5A, 5B and 5C: Efficiency validation on proposed techniques in some embodiments of the invention. FIG. 5A shows host-GPU data transmit time. FIG. 5B shows ordered mask generation time. FIG. 5C shows individual layer inference time.

FIG. 6: Compression Ratio for proposed model in some embodiments of the invention with different batch settings.

FIG. 7: Algorithm of a progressive compression process for an individual-mix block in one embodiment of the invention.

FIG. 8: Example information handling system for implementing one or more of the method and/or framework embodiments of the invention.

Before any embodiments of the invention are explained in detail, it is to be understood that the invention is not limited in its application to the details of embodiment and the arrangement of components set forth in the following description or illustrated in the following drawings. The invention is capable of other embodiments and of being practiced or of being carried out in various ways. Also, it is to be understood that the phraseology and terminology used herein is for the purpose of description and should not be regarded as limiting.

### DETAILED DESCRIPTION

This disclosure generally relates to, among other things, five aspects: an autoregressive (AR) based data compression framework, a system for implementing or facilitating implementation of the framework, and method/system/non-transitory computer-readable storage medium for autoregressive based compression of a dataset. Various features and optional features of these five aspects are recited in the summary.

The following disclosure provides specific example embodiments of these aspects. A skilled person would appreciate that various modifications could be made to these specific example embodiments to provide further embodiments.

### Overview

Some embodiments of the invention provide a lossless data compression framework under a CPU-GPU hardware setting, which includes (e.g., consists only of) matrix addition and matrix multiplication operations. The framework in some embodiments of the invention incorporates a probability estimator arranged to conduct probability estimation for the symbols to be compressed and an arithmetic coder for performing entropy coding based on the estimated probability. In some embodiments, the probability estimator incorporates two types of fully connected neural blocks: individual-batch-aware block and mix-block. The individual-batch-aware block is arranged to facilitate feature extraction for each symbol, and the extracted feature is stored on a cache space located on the GPU to reduce or prevent redundant symbol re-transmission and re-processing. The mix-block is arranged to perform feature mixture and to produce the estimated probability. In some embodiments, a feature cache is utilized to store the extracted features, to ensure or promote efficient CPU-GPU data transmission/communication/processing. More specifically, in some embodiments, the feature cache can reduce or eliminate the need to repeatedly transmit/communicate each of the history symbols from the CPU to the GPU at different processing cycles, as well as reduce or eliminate the need to process the history symbols to extract their features repeatedly at different processing cycles. Additionally, in some embodiments, a learned ordered importance mechanism (instead of complex Gumble-Softmax sampling) is used to simplify or promote hardware compatibility.

The method and/or framework in some embodiments of the invention can be used to compress various types of data, such as image data, video data, audio data, text data, etc., while achieving high compression ratio and/or fast compression speed.

The compression framework in some embodiments employs a multi-stage (e.g., two-stage) approach: feature extraction and correlation modeling. The individual block independently extracts features for each history symbol whereas the mix block fuses these features and performs probability estimation. The framework allows for stacking of multiple individual-mix blocks with different output sizes, thereby enhancing compression performance. Furthermore, in some embodiments, a batch-location-aware modification is introduced in the individual layer to capture the variation in in-batch distributions. Different parameter sets may be assigned to different positions in the batch, thereby optimizing the compression model. The Learned Ordered Mask technique in some embodiments leverages the ordered structure and the features of the data. This technique uses a trainable matrix to learn the importance for the data features, thereby improving the compression performance.

### Specific Example Embodiments

The following specific example embodiments generally relate to faster and/or stronger (more robust) lossless compression with optimized autoregressive framework. Hereinafter, some embodiments of the invention will be described in detail with reference to the drawings.

Faster and Stronger Lossless Compression with Optimized Autoregressive Framework

Most of the work to date has focused on slimming the model architecture. NNCP [5] has a considerable dictionary size of 16384 and a 55M transformer model, leading to a 0.48 KB/s compression speed. Byte stream compressors have been proposed to overcome this problem, as they treat each byte as a symbol and contain smaller dictionaries. Dzip [6] can reach 6.66 KB/s, while TRACE [7] increases the compression speed to 15.8 KB/s. The Multi-Layer Perceptron (MLP)-based compressor OREO [8] explicitly defined the importance order at the beginning of the model to replace attention, achieving a speed of 30 KB/s. Although MLP is hardware friendly, OREO's ordered importance module is based on Gumble-Softmax sampling [9], thus OREO is not yet hardware compatible [8].

A blind spot of these state-of-the-arts is the adaptability of AR structures and compression processes. Section I-A (Background and Motivation) summarize two problems observed in the current design:
1) Duplicated processing problem: Existing AR frameworks use a set of history symbols to estimate the probability of a target symbol. This causes inputs at neighboring time steps to contain significant overlap.
2) In-batch distribution variation problem: The specific batch construction of AR-based compression framework leads to a phenomenon: varied symbol distributions for different positions in the batch. The current design treats different in-batch positions indiscriminately.

The present disclosure is motivated by the aforementioned observations. Some embodiments of the invention propose PAC, a Progressive AR-based Compression framework with a suitable model that can address the duplicated processing problem and in-batch distribution variation problem, while eliminating hardware-unfriendly Gumble-Softmax sampling.

To alleviate the duplicated processing problem, some embodiments of the invention disentangle the probability estimator into two-stage: individual block and mix block. The individual block response for feature extraction on individual symbols while the mix block response for modeling correlation between extracted features. This operation guarantees separate processing of history symbols on the input side. A progressive AR compression framework is further established on proposed individual-mix block. This framework caches the extracted features for reutilization. Thereby, to compress one target symbol, only one latest history symbol needs to be transferred to GPU and performs feature extraction. Features of the rest of the history symbol set can be retrieved from the cache, therefore omit duplicate transmits and feature extractions. On top of current design, a simple and trainable ordered mask generator is proposed to replace Gumble-Softmax sampling. Experiments show that trained ordered masks can achieve the same results as sampled masks but the generation is 20× faster. Another consequence of this modification is that PAC's probability estimation model is now a pure hardware-compatible model, containing only basic matrix multiplication and addition operations. This opens up the opportunity for future neural network-based compressors to offload to edge devices or storage hardware such as SSDs. To address the in-batch distribution variation problem, some embodiments of the invention propose a module that can extract location-specific discriminative features within a batch. The experimental results demonstrate that the proposed framework is able to achieve an average of 130% faster compression across data domains, with an average compression ratio improvement of 3%.

Next, deep-learning based compressors and AR-based compressors that are related to some embodiments of the invention are introduced.

Inventors of the present invention have, through their research, become aware of a new generation of deep-learning-based lossless compressors. These deep-learning-based lossless compressors can offer higher compression ratios. One of the categories is Variational Auto-encoder (VAE) with bits-back coding [10], [11]. The main application of these compressors is in image (image processing). Another category considers the input as an 1D sequence and use auto-regressive (AR) methods to estimate the probability of occurrence of the current symbol directly using its context [6]-[8], [12], [13], and can deal with data without specialized design.

Inventors of the present invention have, through their research, experiments, and/or trials, appreciated that AR-based compressors have improved over the past few years. Table I lists the compression speed of some existing AR-based compressors implemented on the same NVIDIA Geforce RTX 2080 GPU platform. These existing AR-based compressors include Cmix, NNCP, Dzip, TRACE, and OREO. Briefly, Cmix [5] applies Long Short-Term Memory in AR-based compression. NNCP utilizes transformers to estimate the probability whereas Dzip [6] uses recurrent neural networks to estimate the probability. TRACE [7] proposes a slimmed transformer to accelerate the compression procedure. OREO [8] further builds an order model to replace attention to achieve faster compression speed. As shown in Table I, even the fastest OREO can only compress about 1.77 MB/min, i.e., about 30 KB/s. As further illustrated in the following disclosure, the proposed Progressive AR-based Compression framework (PAC) in some embodiments can boost the compression speed to 71.42 KB/s.

TABLE I
Speed of some existing AR-based compressors

| Compressor | Cmix | NNCP | Dzip | TRACE | OREO | PAC |
|---|---|---|---|---|---|---|
| Speed(KB/s) | 0.67 | 0.48 to 2.04 | 6.66 | 15.87 | 30.3 | 71.42 |

Details of some embodiments of the invention will be described hereinafter.

### I—PAC Compression Framework in Some Embodiments

This section presents the motivation and the detailed design of PAC in some embodiments of the invention. First, the existing AR-based compression architecture is analyzed to point out the duplicated processing problem and in-batch distribution variation problem. Then a progressive compression framework is proposed with “individual-mix” architecture, which can resolve the duplicated processing problem. Furthermore, the Gumble-Softmax sampling module in some existing architectures is replaced with a simple trainable matrix, which substantially reduces the computational complexity and provides an opportunity to run the framework on resource-constrained edge devices. In some embodiments, a batch-location-aware structure is proposed to address the in-batch distribution variation problem, which can improve the compression ratio without computational loss.

### A—Background and Motivation

The following provides an analysis of conventional AR-based compression process. Some basic concepts are as follows:
a) Symbol: The basic process unit in compression. Typical categories are bits, bytes, or tokens (a combination of bytes).
b) Target symbol: The symbol to be compressed, denoted as xᵢ. The neural model estimates the probability of xᵢ and feeds it into a coder.
c) History symbols: A set of symbols adjacent to the target symbol, denoted as xᵢ₋ₖ, . . . , xᵢ₋₁, where k is the length of history symbol set. These symbols are the actual input to the model when xᵢ is compressed. In other words, the feature of xᵢ is extracted from its history symbols, but xᵢ itself is not visible to the model. The estimated probability of xᵢ can be expressed as

Pₑ(xᵢ)=P(xᵢ|xᵢ₋₁,xᵢ₋₂, . . . ,xᵢ₋ₖ) (1)

This concept is also referred to as “sequence” or “input sequence” in the following disclosure.

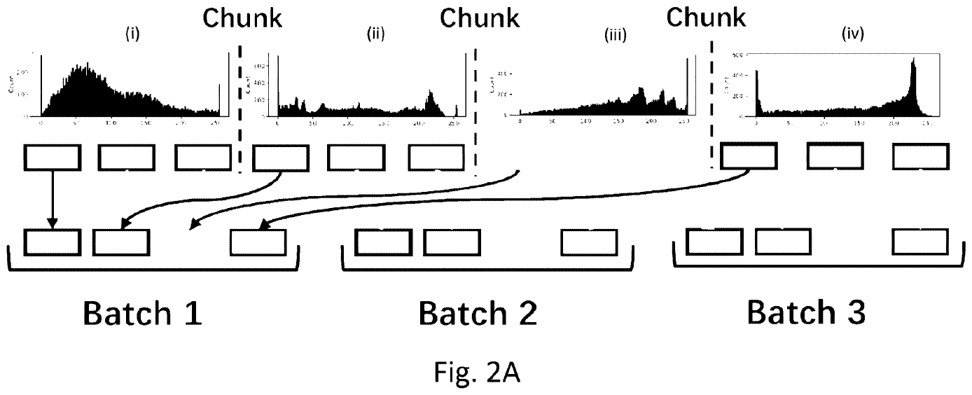

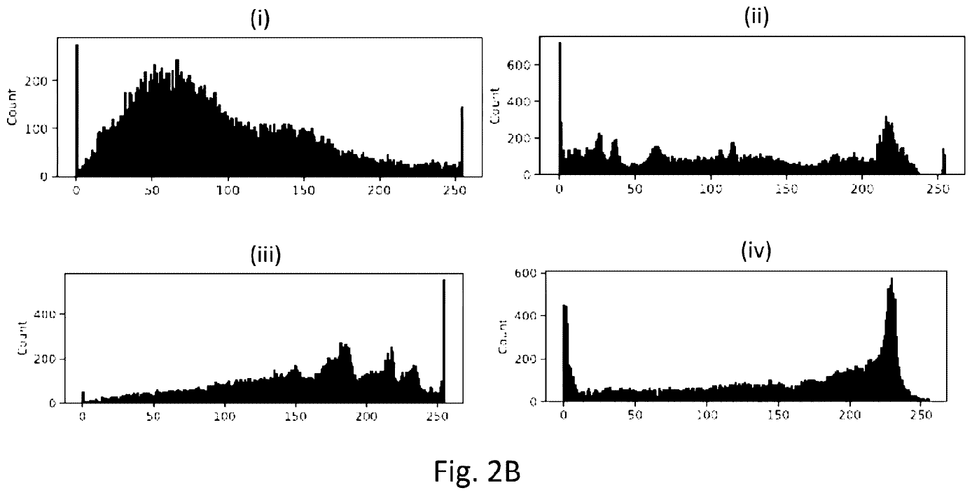

Suppose there is an input sequence X={x₀, x₁, x₂, . . . , x_{B*N}} on host for compression. The compression process includes the following:
1) Structured batch construction. As illustrated in FIG. 2, X is chunked into B sub-sequences of length N to parallize compression procedure. The compressor collects symbols at the same location in each sub-sequence as a batch. For instance, at timestep i, there are B symbols compressed in timestep i, namely xᵢ, x_{i+N}, x_{i+2N}, . . . x_{i+(B-1)N} and these symbols form the batch. At timestep i+1, the compressor compresses xᵢ₊₁, x_{i+N+1}, x_{i+2N+1}, . . . , x_{i+(B-1)N+1}, which constitutes the current batch.
2) Probability estimation. To compress xᵢ, the neural network first estimates Pₑ(xᵢ) using xᵢ₋₁, . . . ,xᵢ₋ₖ. At this stage, xᵢ₋₁, . . . ,xᵢ₋ₖ are transferred from host to GPU and fed into the model. No matter which model is used, the final output of the model is Pₑ(xᵢ). NNCP and TRACE use a transformer to build correlations between history symbols whereas OREO provides a more efficient way using ordered masks and MLP. The approach in some embodiments of the invention is also MLP-based but is more efficient than OREO, due to the utilization of individual-mix block, trainable ordered mask, and/or batch-location-aware design in these embodiments.
3) Coding: Pₑ(xᵢ) and xᵢ are passed to arithmetic coder for entropy coding. Arithmetic coding is applied in this example following the settings in [6]-[8], [13].

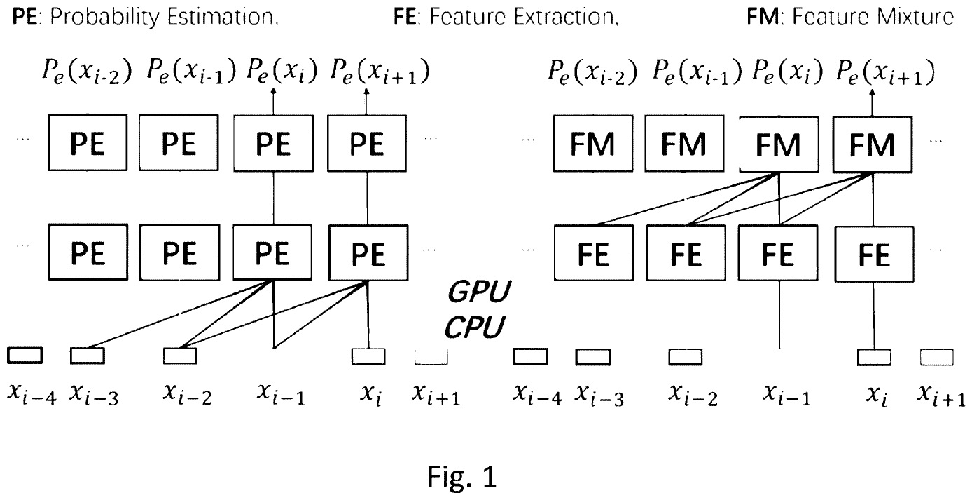

Discussion: Existing standard AR-based compression frameworks have overlaps between inputs on neighboring timesteps. As shown in FIG. 1, to compress xᵢ, xᵢ₋₁, xᵢ₋₂, xᵢ₋₃ are sent to the GPU for probability estimation. At next timestep, to compress xᵢ₊₁, xᵢ, xᵢ₋₁, xᵢ₋₂ are sent to GPU for probability estimation. Here xᵢ₋₁, xᵢ₋₂ are sent and processed repeatedly. Following this setting, if the size of history symbol set is set to k, a history symbol would be sent and processed for k times in total. This phenomenon can be noted as “duplicated processing problem”. In Dzip, TRACE, and OREO, the maximum of k is set as 16, which means 15 symbols are duplicated between input on neighboring timesteps, resulting in an overlap ratio of 93.75%. In NNCP, k takes the value of 64 and the overlap ratio is 98.44%.

The duplicated processing problem arises as a result of treating all history symbols as a whole. For example, the attention-based compressor computes the history symbols' query, key, and value in pairs at every iteration. In this way, queries, keys, and values are recalculated every time a new history symbol is added. Another example is the MLP-based compressor OREO, which first projects history symbols to vectors, then concatenates these vectors to one large feature vector to proceed. This structure dictates that OREO must start over for all history symbols when a history symbol changes.

Structured batch construction is another characteristic of AR-based compression. As mentioned in 1) Structured batch construction, the input sequence can be broken down into several sub-sequences for parallel compression and decompression. The compressor compresses one symbol from each sub-sequence within one timestep. These symbols are usually located at the same position in the sub-sequence, as illustrated in FIG. 2A. At the next timestep, the compressor will compress the symbols at the next adjacent position in each sub-sequence. This structured batch construction leads to batch properties distinct from other machine-learning tasks:
1) Distribution between sub-sequences is varied because the semantic meanings of sub-sequences are much different. Since each sub-sequence corresponds to a specific position in the batch, it can be said that there is a bias in the distribution of symbols at different positions in the batch.
2) Distribution of symbols that appear consecutively at the same batch position are usually close because they belong to the same sub-sequence; adjacent symbols also have overlaps in their history symbol sets.

FIG. 2A illustrates structured batch construction of a 107 bytes ImageNet data, with batch size set to 4096. This example uniformly samples the data distribution of the 1000th, 2000th, 3000th, and 4000th sub-sequences, counts the frequency of occurrences of bytes, and generates distributions. Based on FIG. 2A, it can be seen that the distribution of symbols in the four selected sub-sequences is highly varied. Inventors of the present intention believe that each batch position should have its own parameters when designing a general lossless compression model. These particular parameters can help the model distinguish different sub-sequences, resulting in better compression performance.

### B—Progressive Compression Architecture

In some embodiments, the key to address the duplicated processing problem is disentangling history symbol set's process. Therefore, when the history symbol set changes, the probability estimator does not have to re-compute and re-transmit the full history symbol set. Nonetheless, this solution is inconsistent with existing AR probability estimation designs that aim to entangle the inputs and extract correlations.

Some embodiments of the invention reformulate the AR probability estimation in general-purpose lossless compression as a two-stage task: feature extraction and correlation modeling. These two parts can be implicitly mixed in some existing compressors. Some embodiments of the invention decouple these two parts to separate or strip out the feature extraction part, which can be executed regardless of the relation between symbols. Thus, in some embodiments of the invention, feature extraction of the historical symbols can be conducted separately at the beginning. After separate feature extraction, the correlation modeling part can entangle features and perform probability estimation.

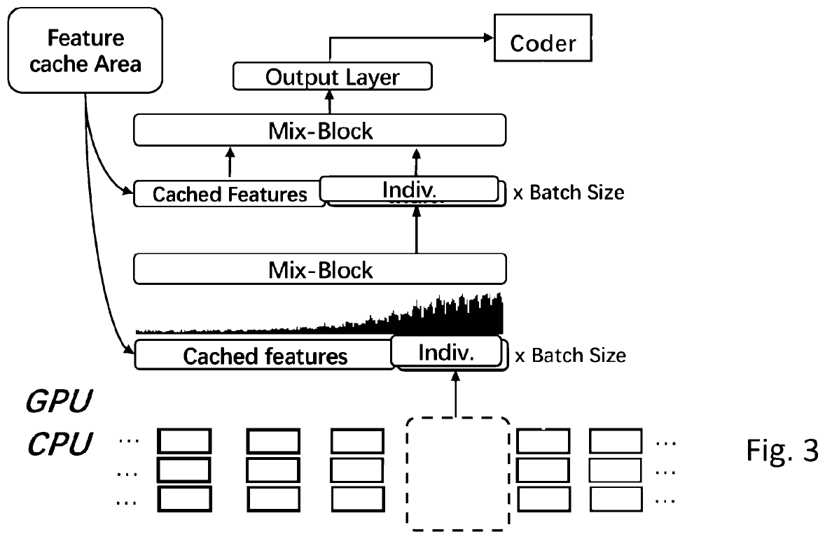

Following the above definition, the basic module of the proposed model, individual-mix block, has two parts: The first part independently extracts features for each history symbol, and the second part fuses features and performs probability estimation (these two parts are named as the individual block and mix block respectively). The individual-mix block can be stacked to further improve performance. It is envisaged that the parameter of proposed block can be dynamically adjusted based on the current compression requirements. FIG. 3 shows an example that stacks two individual-mix blocks with different output sizes.

A feature cache is allocated on GPU, e.g., as the compression begins. Given the history symbol set length k, feature dimension v, batch size b, and data type double, the storage overhead of the feature cache is 4 (k·v·b) bytes. For a compression process in which k=16, v=16, b=8192, the storage overhead is 8 MB, which is negligible when compared with model memory usage (usually in gigabytes level).

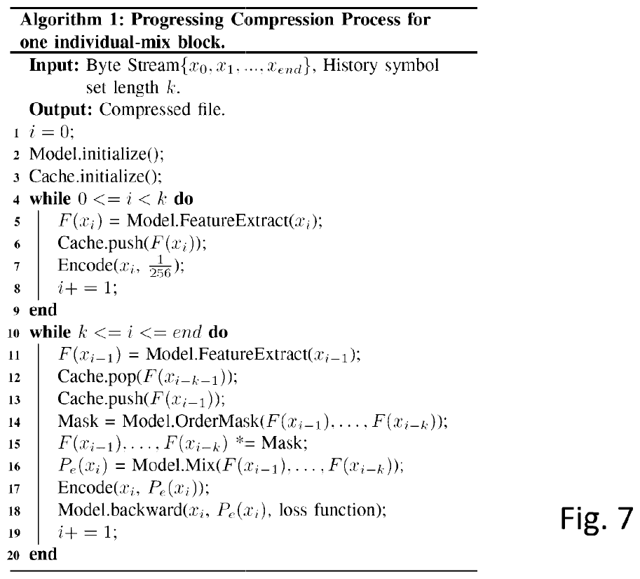

The progressive compression framework in some embodiments of the invention can be described as follows: For every iteration, the individual block extracts feature independently for one distinct history symbol. That is, only one symbol needs to be transmitted and processed per compression iteration. The newly extracted feature is stored in the feature cache. If the number of features in feature cache exceeds k, the oldest feature is discarded. Mix block merges the new feature with other history symbol features fetched from the cache and finally performs probability estimation. Detailed progressive compression process for one individual-mix block in some embodiments of the invention is illustrated/described in Algorithm 1 (see FIG. 7).

In some embodiments, MLP is chosen as the basic structure. In some embodiments, the individual block consists of one fully connected layer whereas the mix block contains two fully connected layers. In some embodiments, both blocks contain a layernorm at the end. As MLP-based architecture lacks the ability to estimate attention on input sequences, an explicit module is needed to build the ordered importance. To this end, existing approaches utilize Gumble-Softmax sampling, which is generally difficult to apply to edge devices like FPGAs. Thus, in some embodiments of the invention, a simple matrix multiplication is used (to replace the Gumble-Softmax sampling), as further described below.

### C—Learned Ordered Importance

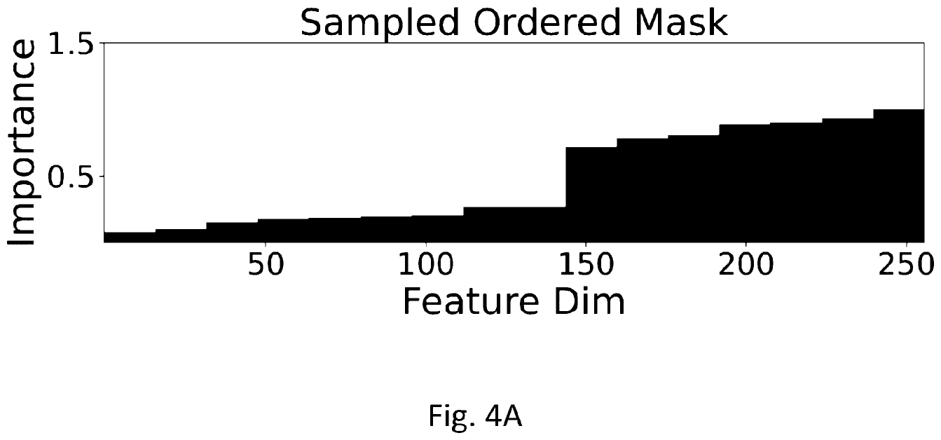

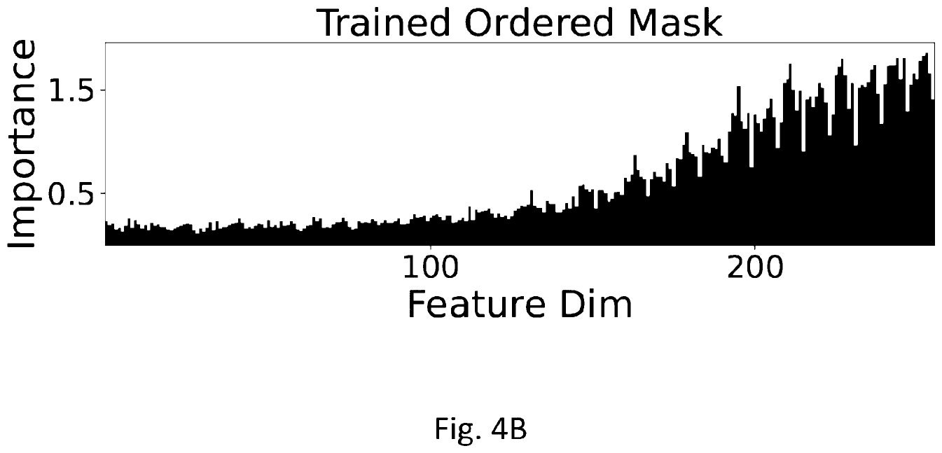

In some embodiments, the ordered mask is an important component of an MLP-based compressor. It highlights the prominent history symbols and is computationally simpler than the attention module of the transformer. The general form of an ordered mask is a one-dimensional vector containing k importance scores for k history symbols. Values in ordered mask should be an approximate uphill trend, e.g., as shown in FIGS. 4A and 4B, which indicates closer symbols usually have a substantially larger influence on the target symbol.

In some existing approaches, ordered masks are generated by the Gumble-Softmax sampling, which requires complex operations such as log and exponential function. This makes the existing general-purpose compressor incompatible with hardware that can only perform matrix addition and multiplication.

To address this issue, in some embodiments of the invention, a trainable 1D vector is introduced to replace the Gumble-Softmax sampling. Instead of assigning importance to each history symbol, learnable importance scores are assigned on the dimension of the extracted features, after the first individual layer. The ordered importance is modeled as:

F(xᵢ₋₁), . . . ,F(xᵢ₋ₖ)=W·{F(xᵢ₋₁), . . . ,F(xᵢ₋ₖ)} (2)

where F(xᵢ₋₁) is the extracted feature of xᵢ₋₁ and W is learned ordered importance. W is joint optimized with other parameters. In some embodiments, the ordered mask is placed after the first individual layer since it will be applied to the whole history symbol set. Thus, the operation has to wait until the first individual layer finished obtaining the features of other history symbols from the cache, as in FIG. 3.

As shown in FIG. 4B, the trained ordered mask can also generate an uphill ordered importance mask. Moreover, the speed of the proposed trained ordered mask is much faster. For samples with a batch size of 512, the proposed method can achieve 0.02 ms per batch whereas the Gumble-Softmax sample method takes 0.3 ms.

### D—Batch-Location-Aware Individual Layer

To address the in-batch distribution variation problem analyzed in Section I-A, in some embodiments, a batch-location-aware compression model is proposed to capture the in-batch distribution variation. Based on the proposed model architecture, the individual layer is modified to assign distinct parameters for different positions in the batch. Only the individual block is modified because it extracts the features of symbols directly, thus being more sensitive to the symbol distribution. The mix block is mainly responsible for feature fusion and remains unchanged in this respect.

The batch-location-aware modification does not increase FLOPs during inference, despite the increased parameters. This is because the amount of computation remains the same. Assuming batch size is N, if only one set of parameters exists, then this set of parameters must be executed N times for N positions in the batch. Modified batch-location-aware individual layer has N sets of parameters, but each parameter set only needs to compute once on one element in the batch, so the overall computation remains the same. Also, the final model size which increases with the growth of parameters should be considered. Nonetheless, the dynamic compression process randomly initializes the probability estimation model on both the transmitter and receiver, therefore eliminating the need to transmit the model [14]. In other words, the model size will generally not affect compression ratios.

### II—Experimental Evaluations

### A—Experimental Setup

Experiments are conducted/benchmarked on seven datasets from various domains. Descriptions of datasets used in the experiments are provided in Table II.

TABLE II
Description of compression datasets
used in the example experiments

| Name | Size | | Description |
|---|---|---|---|
| Book | 1000 | MB | First 1000M byte of BookCorpus [16]. |
| Enwik9 | 1000 | MB | First 1000M byte of the English Wikipedia [17]. |
| Float | 1.1 | GB | Spitzer Space Telescope data [18]. |
| Sound | 842 | MB | ESC [19] Dataset for environmental sound. |
| Image | 1.2 | GB | 100000 pictures from ImageNet. |
| Backup | 1000 | MB | 1000M byte random extract from a disk backup. |
| Silesia | 206 | MB | A compression benchmark [20]. |

In the example experiments, Compression Ratio, Peak GPU Memory Usage, Compression Speed, Latency, and the Floating point operations (FLOPs) are used as metrics. All experimental results are an average of ten repetitive experiments. All experiments are conducted on an 11 GB NVIDIA Geforce RTX 2080 GPU. The proposed method is implemented using Libtorch in C++.

To ensure fairness, in the example experiments, all deep-learning methods follow the dynamic compression procedure, i.e., no pre-training exists. Unless otherwise specified, in the example experiments, the history symbol's number and feature dimension are both 16, the mix-block's first layer output dimensions are 4096. In this example, the experimental probability estimator includes four individual-mix blocks with individual block input/output size=[16, 32, 64, 128]. This is the same as OREO's experimental model settings. In the example, Adam is applied with a learning rate=0.001.

### B—Efficiency Evaluations

The efficiency metrics (including Peak GPU Memory Usage, Model Latency, and the FLOPs) of various existing and the proposed GPU-based compressors in the experiments are shown in Table III.

TABLE III
Peak GPU memory usage, inference latency, and FLOPs of various
existing and proposed GPU-based method in one example
(batch = 128, total 2080 Ti memory size is 10.75 G)

| | Peak GPU Memory | Inference | |
|---|---|---|---|
| Compressor | Usage (GB) | Latency (ms) | FLOPs |
| NNCP | 7.75 | 95.67 | 15.83 × 10¹⁰ |
| Dzip | 6.39 | 5.82 | 7.48 × 10¹⁰ |
| TRACE | 2.02 | 2.08 | 0.34 × 10¹⁰ |
| OREO | 1.18 | 1.54 | 0.12 × 10¹⁰ |
| PAC | 1.07 | 1.54 | 0.1 × 10¹⁰ |

Under batch size 128, PAC only takes 1.07G GPU memory, which is about ½ that of TRACE and about ⅙ of that of Dzip. The latency and the number of FLOPs of PAC are also comparable with the existing state-of-the-art AR-based methods. As shown in Table III, PAC has the same inference time as OREO. This is because the batch size=128 is too small for these two compressors, so the GPU's processing units are not fully utilized. In one example experiment, when batch size=8192, the inference time of PAC is 18.2 ms whereas the inference time of OREO is 23.5 ms. In other words, in this example experiment, PAC is notably faster than OREO.

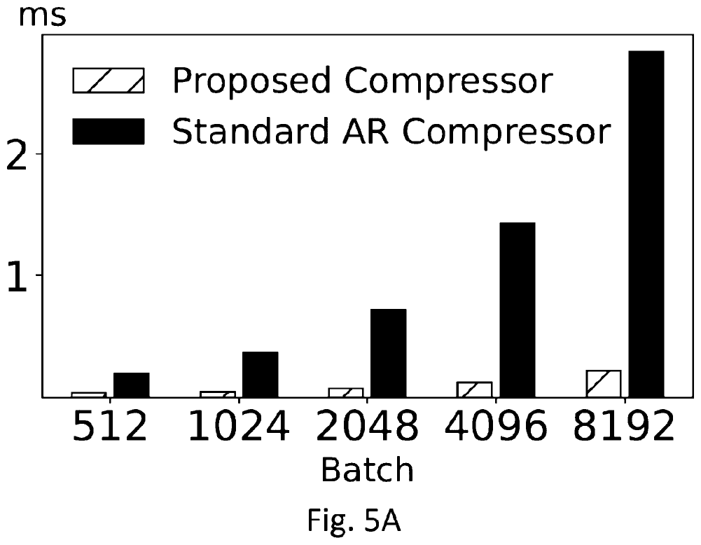

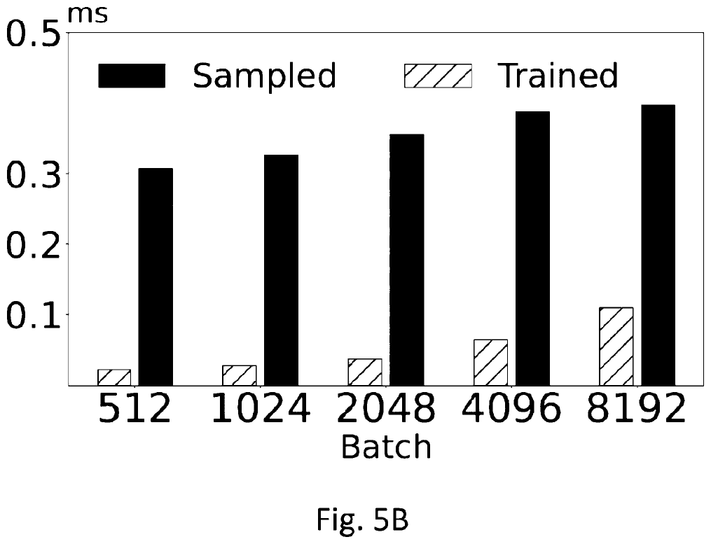

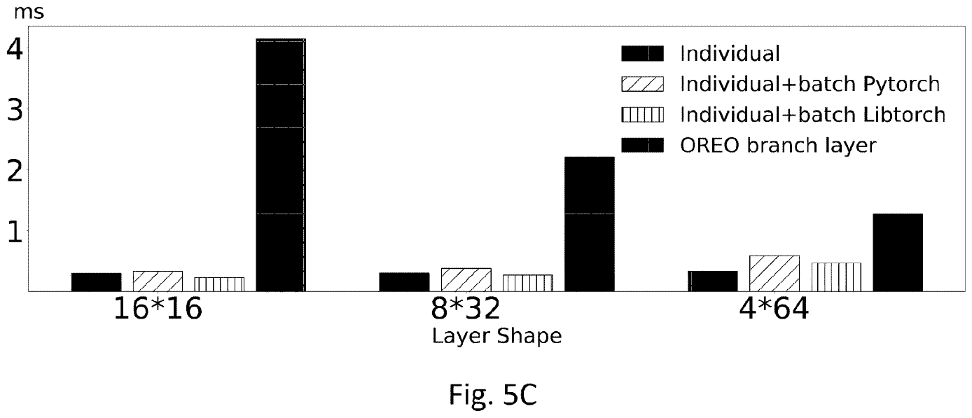

The time breakdown of each key component is investigated. FIG. 5A shows the host-GPU transfer time for standard AR-based compression and PAC. Transfer time has been reduced by a large margin in all batch settings, which demonstrates the effectiveness of the proposed progressive compression framework on data transmission. FIG. 5B shows that the proposed trainable ordered mask can reduce ordered mask generation time from about 0.4 to about 0.1 for a large batch size of 8192. When the batch size is 512, the ordered mask generation time can be reduced from 0.3 ms to 0.01 ms.

The inference speed of individual blocks is tested under different configurations. The results are shown in FIG. 5C. The definition of m*n on the x-axis is m history symbols with each feature vector dimension is n. A more detailed explanation can be found in [8]. Compared with the branch layer of OREO, the proposed individual block is significantly faster across all configurations. The speed of batch-location-aware individual layers in Pytorch and libtorch is also reported. It can be seen that batch-location-aware individual block in python is slightly slower than the original individual block but the libtorch version can generally obtain the same speed. This demonstrates that the proposed batch-location-aware solution generally does not increase computational loads.

### C—Compression Ratio Evaluation

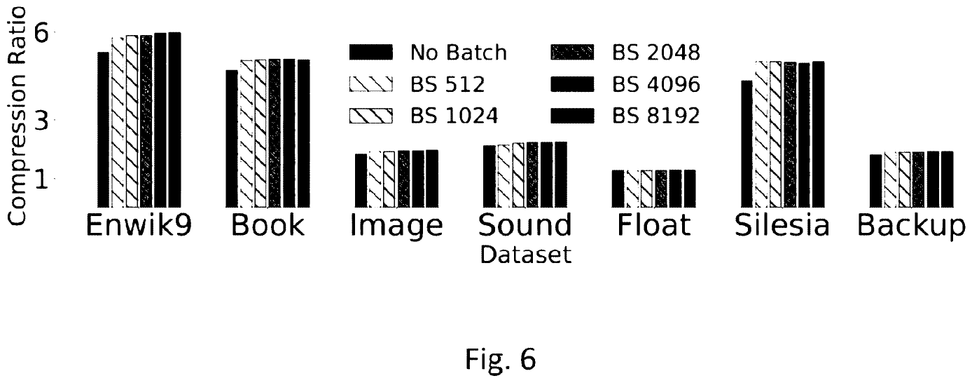

Evaluation of the compression ratio for the proposed model with different batch settings are performed. The results are shown in FIG. 6. After adding batch-location-aware, it can be seen that although the impact of the batch size varies among datasets, the compression ratio improvement brought by batch-location-aware components is general on all data types.

Table IV presents the compression ratio of the proposed compressor and other existing state-of-the-art compressors of different datasets.

TABLE IV
Compression ratios on large datasets

| | Homogeneous Data | | | | | Heterogeneous Data | |
|---|---|---|---|---|---|---|---|
| Method | Enwik9 | Book | Sound | Image | Float | Silesia | Backup |
| Gzip | 3.09 | 2.77 | 1.37 | 1.14 | 1.06 | 3.10 | 1.28 |
| 7z | 4.35 | 3.80 | 1.59 | 1.38 | 1.14 | 4.25 | 1.56 |
| Zstd-19 | 4.24 | 3.73 | 1.40 | 1.16 | 1.10 | 3.97 | 1.36 |
| Dzip | 4.47 | 3.95 | 2.04 | 1.72 | 1.26 | 4.78 | 1.78 |
| TRACE | 5.29 | 4.58 | 2.16 | 1.81 | 1.28 | 4.63 | 1.78 |
| OREO | 5.68 | 4.94 | 2.25 | 1.86 | 1.28 | 4.86 | 1.87 |
| PAC | 5.97 | 5.05 | 2.25 | 1.96 | 1.29 | 4.99 | 1.92 |

As shown in Table IV, Gzip lags far behind other compressors in compression ratios for all data domains. The non-deep-learning compressors such as Zstd-19 and 7z are more advanced. Nevertheless, deep-learning compressors can easily outperform these non-deep-learning compressors. TRACE leverages a slim transformer structure to achieve better compression ratios with faster speeds. OREO addresses the problem of TRACE and improves the compression ratio in all data. PAC in some embodiments of the invention significantly improves over OREO for data compression in all domains. If OREO is used as the baseline, then PAC has a compression improvement of 5.1% and 2.22% on Enwik9 and Book respectively, a compression improvement of 5.38%, and 0.78% on Image and Float respectively. For heterogeneous data Silesia and Backup, PAC is 2.68% better than OREO on both dataset, respectively.

### III—Conclusion

The above disclosure of the specific example embodiments provides, among other things, PAC, a fast and efficient compression framework, by addressing the incompatibility between the AutoRegressive framework and general-purpose lossless compression. Some embodiments of the invention address the duplicated processing problem and/or the in-batch distribution variation problem. Some embodiments of the invention propose a progressive compression framework with an individual-mix block to alleviate the duplicated processing problem, and a trainable matrix multiplication operation to replace hardware-unfriendly Gumble-Softmax sampling. Some embodiments of the invention address or mitigate the in-batch distribution variation problem by capturing the local distribution of different sub-sequences, which can improve compression performance without computational loss. Example experimental results show that PAC in some embodiments of the invention can achieve average to 130% faster compression speed and 3% higher compression ratio than SOTA for various data types.

### Example System

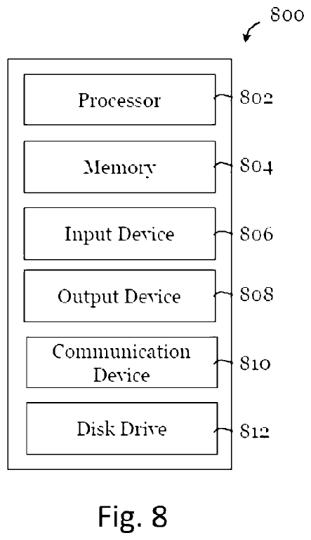

FIG. 8 shows an example information handling system 800 that can be used for implementing one or more of the method and/or framework embodiments of the invention. The information handling system 800 generally comprises suitable components necessary to receive, store, and execute appropriate computer instructions, commands, and/or codes. The main components of the information handling system 800 are a processor 802 and a memory (storage) 804. The processor 802 may include one or more: CPU(s), MCU(s), GPU(s), logic circuit(s), Raspberry Pi chip(s), digital signal processor(s) (DSP), application-specific integrated circuit(s) (ASIC), field-programmable gate array(s) (FPGA), or any other digital or analog circuitry/circuitries configured to interpret and/or to execute program instructions and/or to process signals and/or information and/or data. In some embodiments, the processor 802 comprises at least one CPU and at least one GPU, to provide a CPU-GPU hardware setting. The memory 804 may include one or more volatile memory (such as RAM, DRAM, SRAM, etc.), one or more non-volatile memory (such as ROM, PROM, EPROM, EEPROM, FRAM, MRAM, FLASH, SSD, NAND, NVDIMM, etc.), or any of their combinations. Appropriate computer instructions, commands, codes, information and/or data may be stored in the memory 804. Computer instructions for executing or facilitating executing the method and/or framework embodiments of the invention may be stored in the memory 804. The processor 802 and memory (storage) 804 may be integrated or separated (and operably connected). Optionally, the information handling system 800 further includes one or more input devices 806. Example of such input device 806 include: keyboard, mouse, stylus, image scanner, microphone, tactile/touch input device (e.g., touch sensitive screen), image/video input device (e.g., camera), etc. Optionally, the information handling system 800 further includes one or more output devices 808. Example of such output device 808 include: display (e.g., monitor, screen, projector, etc.), speaker, headphone, earphone, printer, additive manufacturing machine (e.g., 3D printer), etc. The display may include a LCD display, a LED/OLED display, or other suitable display, which may or may not be touch sensitive. The information handling system 800 may further include one or more disk drives 812 which may include one or more of: solid state drive, hard disk drive, optical drive, flash drive, magnetic tape drive, etc. A suitable operating system may be installed in the information handling system 800, e.g., on the disk drive 812 or in the memory 804. The memory 804 and the disk drive 812 may be operated by the processor 802. Optionally, the information handling system 800 also includes a communication device 810 for establishing one or more communication links (not shown) with one or more other computing devices, such as servers, personal computers, terminals, tablets, phones, watches, IoT devices, or other wireless computing devices. The communication device 810 may include one or more of: a modem, a Network Interface Card (NIC), an integrated network interface, a NFC transceiver, a ZigBee transceiver, a Wi-Fi transceiver, a Bluetooth® transceiver, a radio frequency transceiver, a cellular (2G, 3G, 4G, 5G, above 5G, or the like) transceiver, an optical port, an infrared port, a USB connection, or other wired or wireless communication interfaces. Transceiver may be implemented by one or more devices (integrated transmitter(s) and receiver(s), separate transmitter(s) and receiver(s), etc.). The communication link(s) may be wired or wireless for communicating commands, instructions, information and/or data. In one example, the processor 802, the memory 804 (optionally the input device(s) 806, the output device(s) 808, the communication device(s) 810 and the disk drive(s) 812, if present) are connected with each other, directly or indirectly, through a bus, a Peripheral Component Interconnect (PCI), such as PCI Express, a Universal Serial Bus (USB), an optical bus, or other like bus structure. In one embodiment, at least some of these components may be connected wirelessly, e.g., through a network, such as the Internet or a cloud computing network. A person skilled in the art would appreciate that the information handling system 800 shown in FIG. 8 is merely an example and that the information handling system 800 can in other embodiments have different configurations (e.g., include additional components, has fewer components, etc.).

Although not required, one or more embodiments described with reference to the Figures can be implemented as an application programming interface (API) or as a series of libraries for use by a developer or can be included within another software application, such as a terminal or computer operating system or a portable computing device operating system. In one or more embodiments, as program modules include routines, programs, objects, components, and data files assisting in the performance of particular functions, the skilled person will understand that the functionality of the software application may be distributed across a number of routines, objects and/or components to achieve the same functionality desired herein.

It will also be appreciated that where the methods and systems of the invention are either wholly implemented by computing system or partly implemented by computing systems then any appropriate computing system architecture may be utilized. This will include stand-alone computers, network computers, dedicated or non-dedicated hardware devices. Where the terms “computing system” and “computing device” are used, these terms are intended to include (but not limited to) any appropriate arrangement of computer or information processing hardware capable of implementing the function described.

### Example Features of Some Embodiments

The framework in some embodiments of the invention includes one or more of the following features:
1. Progressive Auto-regressive Compression: Some embodiments of the invention introduce a progressive compression architecture that addresses the issue of duplicated processing. By decoupling feature extraction and correlation modeling, the architecture can reduce redundant computations, which leads to more efficient compression.
2. Individual-Mix Blocks: Some embodiments of the invention utilize individual-mix blocks, which includes or consist of: the individual block and the mix block. Each individual block is arranged to independently extract features for a respective history symbol whereas the mix block is arranged to fuse these features and performs probability estimation. This modular approach enhances flexibility and performance.
3. Learned Ordered Importance: To highlight the prominent history symbols, some embodiments of the invention introduce a learned ordered importance mechanism. Instead of using complex Gumble-Softmax sampling, some embodiments of the invention employ a trainable 1D vector to assign importance scores to the extracted features. This simplifies the computation and makes it compatible with hardware constraints.
4. Batch-Location-Aware Individual Layer: Some embodiments of the invention incorporate a batch-location-aware modification in the individual layer to address the in-batch distribution variation problem. By assigning distinct parameters for different positions in the batch, some embodiments of the invention capture the variations in symbol distribution and improve compression performance.
5. Hardware-Friendly Operations: Some embodiments of the invention are designed to be hardware-friendly, and are particularly suited for devices with limited computational capabilities. Some embodiments of the invention primarily utilize matrix addition and multiplication operations, hence are more efficient for implementation on hardware platforms.

### Example Functions/Applications of Some Embodiments

One function of some embodiments of the invention is to provide a general-purpose lossless compression algorithm that can effectively reduce the size of data with little or without any loss of information. Some embodiments of the invention utilize a neural network-based approach to capture correlations and patterns in the data and generate compressed representations. This can be achieved through various innovative features, including, e.g., two-stage compression framework, individual layer with batch-aware design, hardware-friendly ordered mask construction, etc.

One function of some embodiments of the invention is to compress various types of data, including text, video, image, audio, and other forms of information, in a versatile and efficient manner. It enables the efficient storage, transmission, and processing of data by significantly reducing its size, making it suitable for a wide range of applications.

The function of some embodiments of the invention can extend beyond compression. Some embodiments of the invention also include the decompression process, in which the compressed data can be efficiently reconstructed to its original form. This ensures that the compressed data can be accurately recovered and used for subsequent analysis, processing, and/or presentation.

The PAC in some embodiments of the invention can have numerous and various applications. For example, the PAC in some embodiments of the invention can be used in scenarios in which IoT device(s) transmits data over a network, such as in smart homes, industrial automation, and healthcare. For example, the PAC in some embodiments of the invention can be applied to non-IoT applications, such as video streaming, cloud storage, etc. The PAC in some embodiments of the invention can potentially significantly reduce the cost and energy consumption of IoT devices and data centers while improving their performance and/or reliability.

Embodiments of the invention are applied in the field of data compression, and can be used in various industries and domains. Some example applications of some embodiments of the invention include:
1. Data Storage: Some embodiments of the invention can be applied in data storage systems, such as hard drives, solid-state drives (SSDs), cloud storage platforms, etc. By reducing the size of data, some embodiments of the invention enable more efficient utilization of storage space, allowing for larger capacities and cost savings.
2. Data Transmission: Some embodiments of the invention can be used in data transmission systems, including network communication protocols and internet-based applications. Compressing data before transmission can reduce bandwidth requirements, enhance network performance, and/or decrease transmission time.
3. Multimedia Compression: some embodiments of the invention is well-suited for compressing multimedia data, such as image, video, and audio files. some embodiments of the invention enable efficient storage and streaming of multimedia content, facilitating applications in digital media, entertainment, video conferencing, online streaming platforms, etc.
4. IoT and Edge Devices: With the proliferation of Internet of Things (IoT) devices and edge computing, some embodiments of the invention can be utilized to compress data generated by sensors and devices with limited resources. This may reduce energy consumption, extend battery life, and enable real-time processing and analysis of IoT data.
5. Data Analytics: The compressed data generated by some embodiments of the invention can be efficiently used in data analytics and machine learning applications. It allows for faster processing, lower computational requirements, and improved insights from large datasets.
6. Archiving and Backup: The compression capabilities in some embodiments of the invention make them suitable for archiving and backup systems. It helps reduce the storage footprint of archived data, ensuring long-term preservation and retrieval of information.

The above applications are merely examples, and the invention is versatile hence can be applied to various domains where efficient data compression is required.

The invention in embodiments of the invention may be implemented in a wide range of industries, such as IoT, AR/VR, video streaming, medical imaging, etc., just to name a few. In one example, in the IoT space, PAC in some embodiments can help reduce the bandwidth consumption of connected devices, making it easier to transmit data over limited network connections. In one example, in AR/VR, PAC in some embodiments can help reduce the amount of data that needs to be transmitted to the device of the user, leading to faster load times and smoother experiences. In one example, in video streaming, PAC in some embodiments can help reduce the amount of bandwidth required to transmit high-quality video, leading to cost savings for both content providers and consumers. In one example, in medical imaging, PAC in some embodiments can help reduce the amount of data that needs to be transmitted between medical devices, leading to faster diagnosis and treatment times. In one example, PAC data compression framework in some embodiments can also be applied to cloud servers and data centers. By reducing the amount of data that needs to be transmitted between servers and data centers, PAC in some embodiments can help to improve the efficiency of data transfer and reduce the overall bandwidth consumption. This can lead to significant cost savings for cloud service providers and data center operators. Additionally, the innovative hardware-friendly design of PAC in some embodiments can also help to improve the performance of data center hardware, leading to faster processing times and improved overall system performance.

In one example, companies with cloud servers containing huge amount of cold data that needs efficient storage may find the invention particularly useful. In one example, autonomous driving companies that need efficient data transmission among cars may find the invention particularly useful (as a versatile compression method can help them reduce bandwidth and make the communication faster).

### Example Advantages of Some Embodiments

Some embodiments of the invention include one or more of the following advantages. Some embodiments of the invention include one or more additional or alternative advantages not described or illustrated herein.
1. Improved Compression Efficiency: Some embodiments of the invention address the issue of duplicated processing in existing AR-based compression frameworks. By disentangling the history symbol set's process and utilizing independent feature extraction, the framework reduces redundant computations and achieves higher compression efficiency compared to traditional approaches.
2. Enhanced Compression Ratios: The batch-location-aware individual layer modification in the framework in some embodiments of the invention can effectively handle in-batch distribution variation. By assigning distinct parameters to different positions in the batch, the framework in some embodiments can capture the diverse semantic meanings of sub-sequences, leading to improved compression ratios and better overall compression performance.
3. Hardware Friendly: The PAC in some embodiments of the invention is hardware-friendly. Unlike many neural network-based compressors, PAC in some embodiments of the invention is specifically designed to utilize only matrix addition and multiplication operations. This characteristics makes it highly compatible with different hardware architectures, including edge devices and resource-constrained systems. The reduced computational complexity of PAC in some embodiments of the invention enables efficient implementation and deployment across a wide range of platforms.
4. Real-Time Compression: PAC in some embodiments of the invention offer the potential for real-time compression and decompression of data. Its optimized architecture and hardware-friendly operations enable fast processing speeds, making it suitable for applications requiring on-the-fly or online compression and decompression, such as streaming data, video conferencing, real-time sensor data analysis, etc.
5. Scalability and Future Adaptability: The modular design of PAC in some embodiments of the invention allows for scalability and adaptability. In some embodiments, the individual-mix block structure can be stacked to enhance performance further, providing flexibility in optimizing compression algorithms for specific use cases. Additionally, the model in some embodiments can be trained and fine-tuned with additional data to improve compression efficiency and adapt to evolving data patterns.
6. Versatile and General-Purpose: The progressive compression framework in some embodiments of the invention is designed to be versatile and is applicable to various data compression tasks. For example, it can be utilized in a wide range of applications, including image and video compression, file compression, cloud storage, data transmission, and archival systems. Its adaptability and/or flexibility make it a valuable tool in different domains.

### Possible Variations

It will be appreciated by a person skilled in the art that variations and/or modifications may be made to the described and/or illustrated embodiments of the invention to provide other embodiments of the invention. The described and/or illustrated embodiments of the invention should therefore be considered in all respects as illustrative, not restrictive. Example optional features of some embodiments of the invention are provided in the summary and the description. Some embodiments of the invention may include one or more of these optional features. Some embodiments of the invention may lack one or more of these optional features.

### REFERENCES

[1] DKRZ, “Unique status among german high-performance computing centres.” 2021.
[2] Wikipedia, “Amazon web service.” 2020.
[3] P. Deutsch, “GZIP file format specification version 4.3,” RFC, vol. 1952.
[4] Y. Collet, “Zstd github repository from facebook,” 2016.
[5] B. Knoll, “Cmix.” 2014.
[6] G. Mohit et al., “Dzip: Improved general-purpose loss less compression based on novel neural network modeling,” in DCC′2021.
[7] Y. Mao et al., “Trace: A fast transformer-based general-purpose lossless compressor,” in WWW, pp. 1829-1838, 2022.
[8] Y. Mao et al., “Accelerating general-purpose lossless compression via simple and scalable parameterization,” in MM′22, pp. 3205-3213, 2022.
[9] Cui et al., “Fully nested neural network for adaptive compression and quantization,” in Proceedings of the Twenty-Ninth International Joint Conference on Artificial Intelligence, IJCAI-20, pp. 2080-2087, International Joint Conferences on Artificial Intelligence Organization, 7 2020.
[10] Kingma et al., “Bit-swap: Recursive bits-back coding for lossless compression with hierarchical latent variables,” in ICML, pp. 3408-3417, PMLR, 2019.
[11] van den Berg et al., “Idf++: Analyzing and improving integer discrete flows for lossless compression,” in ICLR, 2020.
[12] B. Knoll, “Tensorflow-compress,” 2016.
[13] F. Bellard, “Nncp: Lossless data compression with neural networks.” 2019.
[14] C. Zhang et al., “Osoa: One-shot online adaptation of deep generative models for lossless compression,” NIPS, 2021.
[15] Paszke et al., “Pytorch: An imperative style, high-performance deep learning library,” NIPS, 2019.
[16] Vaswani et al., “Attention is all you need,” NIPS, vol. 30, 2017.
[17] M. Mahoney, “Large text compression benchmark.” 2006.
[18] M. Burtscher et al., “Fpc: A high-speed compressor for double-precision floating-point data,” IEEE Transactions on Computers, 2009.
[19] K. J. Piczak, “ESC: Dataset for Environmental Sound Classification,” 2015.
[20] S. Deorowicz, “Silesia dataset.” 1985.

1. A method for autoregressive based compression of a dataset with a plurality of data units, comprising:
using a neural network based probability estimator, determining a probability associated with a target data unit based on one or more previous data units associated with the target data unit; and
using a coder, coding the target data unit based on the target data unit and the determined probability associated with the target data unit.

2. The method of claim 1, wherein determining the probability associated with the target data unit comprises:
performing feature extraction operation for each respective one of the one or more previous data units associated with the target data unit to extract one or more features of the one or more previous data units associated with the target data unit; and
performing feature mixture operation based on the one or more extracted features of the one or more previous data units associated with the target data unit to perform correlation modelling and to determine the probability associated with a target data unit.

3. The method of claim 2,
wherein the one or more extracted features of the one or more previous data units comprise a plurality of extracted features of a plurality of previous data units; and
wherein the method further comprises:
prior to performing the feature mixture operation, assigning respective importance score to each of the extracted features to facilitate performing of the feature mixture operation.

4. The method of claim 3, wherein the assigning comprises performing matrix addition and multiplication for estimation of importance for the extracted features and/or applying a trainable or trained ordered mask to the extracted features.

5. (canceled)

6. The method of claim 4, wherein the trainable or trained ordered mask comprises a 1D vector.

7. The method of claim 2, wherein the feature extraction operation is performed by one or more individual blocks of the neural network based probability estimator, each of the one or more individual blocks is arranged for performing feature extraction operation on a respective one of the one or more previous data units.

8. The method of claim 7,
wherein each of the one or more individual blocks respectively comprises a fully connected layer; and/or
wherein the one or more individual blocks are multilayer perceptron (MLP) based or wherein the feature mixture operation is performed by a mix block of the neural network based probability estimator or both the one or more individual blocks are multilayer perceptron (MLP) based and the feature mixture operation is performed by a mix block of the neural network based probability estimator.

9. (canceled)

10. The method of claim 8,
wherein the mix block comprises a plurality of fully connected layers; and/or
wherein the mix block is multilayer perceptron (MLP) based and/or wherein each of the one or more individual blocks comprises one fully connected layer, and the mix block comprises two fully connected layers.

11. (canceled)

12. The method of claim 2, further comprising:
prior to performing the feature extraction operation, transmitting the one or more previous data units associated with the target data unit from a first processor to a second processor, and
wherein the feature extraction operation and the feature mixture operation are performed at the second processor.

13. The method of claim 12, further comprising:
caching the extracted features of the one or more previous data units in a cache of the second processor.

14. The method of claim 13, further comprising:
prior to performing the feature mixture operation, retrieving the one or more extracted features of the one or more previous data units from the cache of the second processor.

15. The method of claim 12,
wherein the first processor comprises a CPU, and the second processor comprises a GPU.

16. The method of claim 6,
wherein the plurality of data units of the dataset form a plurality of data subsets each including multiple data units,
wherein the dataset defines a plurality of batches each including one respective data unit from each respective one of the data subsets; and
wherein the data units in the same batch are processed in the same processing cycle, and the data units in different batches are processed in different processing cycles.

17. The method of claim 16, wherein in each processing cycle, each of the data units in the corresponding batch corresponds to a respective target data unit and/or wherein each batch respectively includes data units taken from the same location in the plurality of data subsets and/or wherein the one or more individual blocks of the neural network based probability estimator are one or more batch-location-aware individual blocks.

18. (canceled)

19. (canceled)

20. The method of claim 1, wherein the coder comprises an entropy coder or an arithmetic coder.

21. The method of claim 1, wherein the dataset comprises image data, video data, text data, or audio data.

22. The method of claim 1, wherein each of the plurality of data units respectively correspond to bit(s), byte(s), or token(s).

23. A system for autoregressive based compression of a dataset with a plurality of data units, comprising:
one or more processors; and
memory storing one or more programs configured to be executed by the one or more processors, the one or more programs including instructions for performing or facilitating performing of the method of claim 1.

24. The system of claim 23, wherein the one or more processors comprises a CPU and a GPU.

25. A non-transitory computer-readable storage medium storing one or more programs configured to be executed by one or more processors, the one or more programs including instructions for performing or facilitating performing of the method of claim 1.
